(19) United States
(12) Patent Application Publication
(10) Pub. No.: US 2020/0106005 A1
(43) Pub. Date: Apr. 2, 2020

(54) MAGNETORESISTIVE DYNAMIC RANDOM ACCESS MEMORY CELL

(71) Applicant: Mohammad Kazemi, Rochester, NY (US)

(72) Inventor: Mohammad Kazemi, Rochester, NY (US)

(21) Appl. No.: 16/617,199

(22) PCT Filed: May 29, 2018
(86) PCT No.: PCT/US18/34865

§ 371 Date: Nov. 26, 2019

Related U.S. Application Data
(60) Provisional application No. 62/512,270, filed on May 30, 2017.

(51) Int. Cl. H01L 43/08; H01L 43/02; H01L 45/00; H01L 27/22; H01L 27/24; H01L 27/108

(52) U.S. Cl. CPC H01L 43/08; H01L 43/02; H01L 27/10805; H01L 27/222; H01L 27/2463; H01L 45/06

(57) ABSTRACT

A magnetoresistive dynamic random access memory (MDRAM) cell is described. A hybrid memory cell includes a first transistor having a first source/drain electrode coupled to a charge storage node and a gate of a second transistor. A first transistor second source/drain electrode is coupled to a dynamic bit-line, and a gate of the first transistor coupled to a dynamic bit word-line. A resistive memory element is coupled between a select line and the second transistor first source/drain electrode. A third transistor includes a third transistor first source/drain electrode which is coupled to a second source/drain electrode of the second transistor. A third transistor second source/drain electrode is coupled to a nonvolatile bit-line. A gate of the third transistor is coupled to a nonvolatile bit word-line. A memory array of hybrid memory cells and a hybrid memory cell method is also described.

### CROSS-REFERENCE TO RELATED APPLICATIONS

This application claims priority to and the benefit of co-pending U.S. provisional patent application Ser. No. 62/512,270, MAGNETORESISTIVE DYNAMIC RANDOM ACCESS MEMORY CELL, filed May 30, 2017, which application is incorporated herein by reference in its entirety.

### FIELD OF THE APPLICATION

The application relates to a hybrid memory cell, particularly a hybrid memory cell with a dynamic bit and a nonvolatile bit.

### BACKGROUND

Embedded memories are used in the design of integrated circuits such as microprocessors and microsystems. Embedded memories include arrays of memory cells.

### SUMMARY

According to one aspect, a hybrid memory cell includes a first transistor having a first source/drain electrode coupled to a charge storage node and a gate of a second transistor. A first transistor second source/drain electrode is coupled to a dynamic bit-line, and a gate of the first transistor coupled to a dynamic bit word-line. A resistive memory element is coupled between a select line and the second transistor first source/drain electrode. A third transistor includes a third transistor first source/drain electrode which is coupled to a second source/drain electrode of the second transistor. A third transistor second source/drain electrode is coupled to a nonvolatile bit-line. A gate of the third transistor is coupled to a nonvolatile bit word-line.

In one embodiment, a nonvolatile bit of a hybrid memory cell resides in the resistive memory element, and a dynamic bit of the hybrid memory cell simultaneously resides as a charge state at the charge storage node, such that the hybrid memory cell has an independent and a non-destructive access to both of the nonvolatile bit and the dynamic bit.

In another embodiment, a read of the nonvolatile bit and a write of the dynamic bit can happen simultaneously and without contention.

In yet another embodiment, the charge storage node includes a gate capacitance of the second transistor.

In yet another embodiment, the charge storage node further includes a drain/source capacitance of the first transistor.

In yet another embodiment, the second transistor is ON, independent of said dynamic bit stored in the charge storage node.

In yet another embodiment, a “1” written into said charge storage node corresponds to a charge storage node voltage of (V₁-Vₜₕ), where V₁ is a voltage of a write bit-line and Vₜₕ is a threshold voltage of the first transistor.

In yet another embodiment, the resistive memory element includes a magnetic tunnel junction (MTJ).

In yet another embodiment, the resistive memory element includes a memristive device.

In yet another embodiment, the resistive memory element includes a phase change memory (PCM) device.

In yet another embodiment, the hybrid memory cell further includes a plurality of additional hybrid memory cells in a column of memory cells of a memory array.

According to another aspect, a memory array includes a plurality of columns of hybrid memory cells. Each hybrid memory cell of each column includes a dynamic bit charge storage node coupled to and accessed via a dynamic bit word-line, a dynamic bit-line, and a select line. A nonvolatile bit resistive memory element is coupled to and accessed via a nonvolatile bit-line, a nonvolatile bit word-line, and the select line, such that there is a simultaneous, independent and nondestructive access to both of the dynamic bit and the nonvolatile bit.

According to yet another aspect, a hybrid memory cell method includes providing a hybrid memory cell including a dynamic bit having a charge storage node and a nonvolatile bit including a resistive memory element; writing to a dynamic bit charge node at a gate of second transistor of a hybrid memory cell via dynamic bit-line coupled to a first transistor; or writing to a nonvolatile bit resistive memory element of the hybrid memory cell via a nonvolatile bit-line coupled to a third transistor; and wherein the nonvolatile bit and the dynamic bit of the hybrid memory cell simultaneously reside in the hybrid memory cell such that the hybrid memory cell has an independent and a non-destructive access to both of the nonvolatile bit and the dynamic bit.

In one embodiment, the step of independent and a non-destructive access includes a read or write of either of the dynamic bit or the nonvolatile bit by a sense amplifier.

The foregoing and other aspects, features, and advantages of the application will become more apparent from the following description and from the claims.

### BRIEF DESCRIPTION OF THE DRAWINGS

The features of the application can be better understood with reference to the drawings described below, and the claims. The drawings are not necessarily to scale, emphasis instead generally being placed upon illustrating the principles described herein. In the drawings, like numerals are used to indicate like parts throughout the various views.

FIG. 1A shows a schematic of an exemplary MDRAM Cell according to the Application;

FIG. 1B shows how a “1” is written into the dynamic bit of the memory cell of FIG. 1A;

FIG. 1C shows how a “0” is written into the dynamic bit of the memory cell of FIG. 1A;

FIG. 1D shows how a “1” is written into the nonvolatile bit of the memory cell of FIG. 1A;

FIG. 1E shows how a “0” is written into the nonvolatile bit of the memory cell of FIG. 1A;

FIG. 2 is a schematic diagram illustrating an exemplary arrangement of a sense amplifier to read the data stored within the dynamic bit or the nonvolatile bit of a MDRAM cell;

FIG. 3 shows an exemplary graph illustrating the voltage level at storage node Cₛ as a function of time;

FIG. 4 shows a schematic diagram which illustrates Leakage currents that cause a collapse of the datum stored within the storage node Cₛ; and

FIG. 5 shows an exemplary use of an MDRAM memory cell.

### DETAILED DESCRIPTION

Part 1 Background

Embedded memories have been increasingly used in integrated circuits, such as, for example, microprocessors and microsystems. Static random access memory (SRAM) cells have been used to implement embedded memory systems. Such SRAM based memory systems, although sufficiently fast, suffer from low density and high static power dissipation. Replacing SRAM with dense, high speed, and low energy memory cells that are compatible with the standard CMOS process has therefore been widely considered. Dynamic random access memory (DRAM) gain cell and magnetoresistive random access memory (MRAM) cell operating based on spin transfer torque (STT) are two potential candidates which have been considered for replacing SRAM cell in embedded memories.

In a DRAM gain cell, conventionally, there is one transistor which retains one bit of information, one transistor which controls the write operation, and one transistor which controls the read operation. During the retention time, the stored bit deteriorates due to leakage. Hence, the memory cell requires to be frequently refreshed, thereby causing large static power dissipation particularly when the bit is retained for a long period of time. Furthermore, when the cell is in the refresh cycle, systems that need to access the memory cell are required to wait until the refresh process is complete, thereby degrading system performance. As the gate oxide layer of transistors continue to become thinner due to technology scaling, for example, the leakage current in memory cells has become an increasingly challenging design parameter.

In an STT-MRAM cell, there exists a magnetic tunnel junction (MTJ) device which retains one bit of information and a transistor which controls the read and write operation. An MTJ is a nonvolatile device, thereby avoiding the need for refresh during the retention time. Nevertheless, faster writing of a bit into an STT-MRAM cell requires exponentially larger current, thereby dissipating significantly more power during the write cycle and necessitating a larger access transistor. Such increased power consumption compromises the memory density and causes an inherent tradeoff between the speed and density/power in an STT-MRAM cell, which limits the application of the cell when a high speed and energy efficient memory is required.

Part 2 Magnetoresistive Dynamic Random Access Memory (MDRAM) Cell

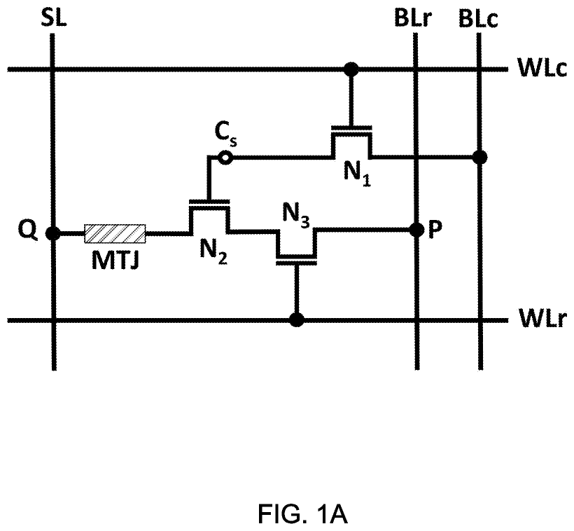

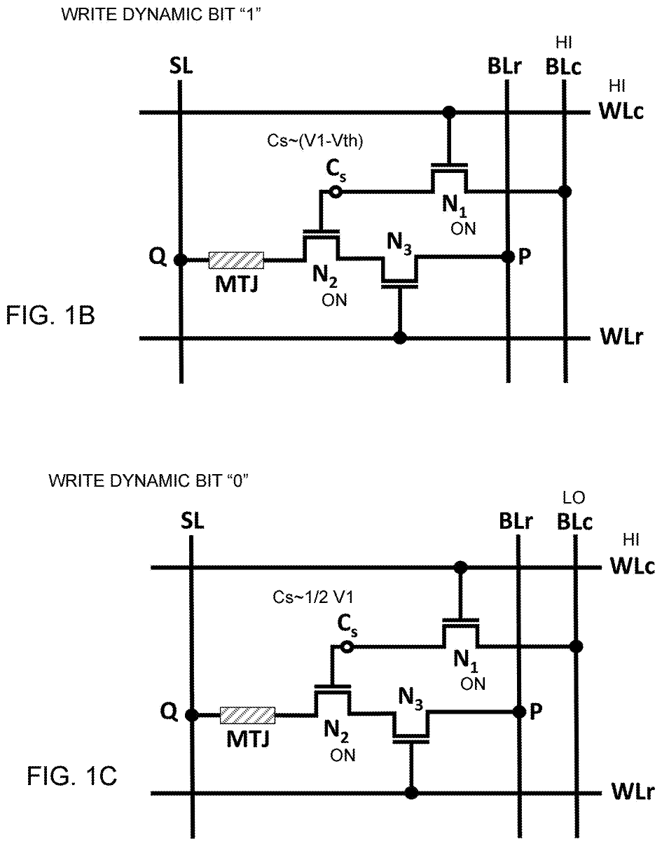

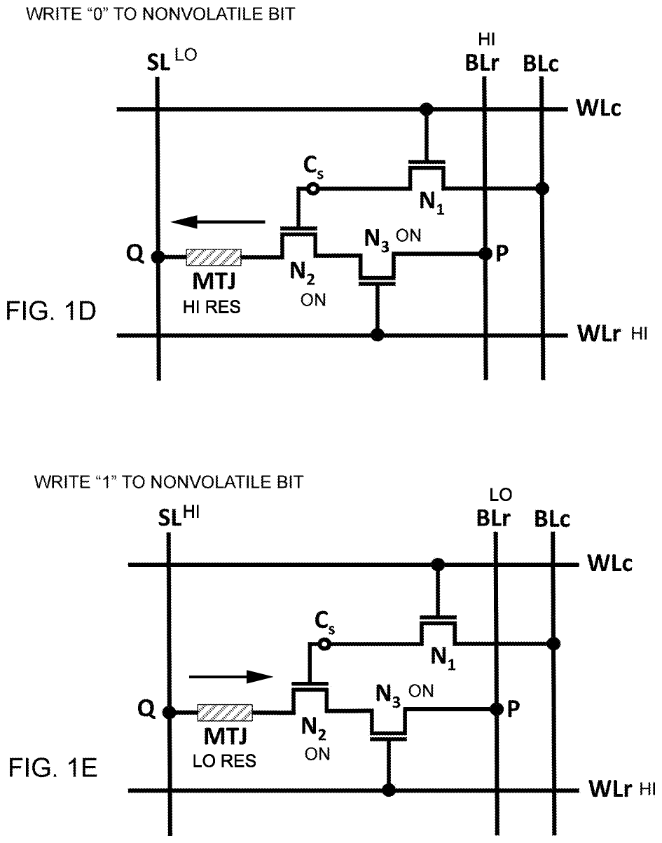

FIG. 1A illustrates the schematic diagram of an exemplary embodiment of a new MDRAM cell circuit topology with of an MTJ device and three n-channel metal oxide semiconductor (NMOS) transistors. The new MDRAM cell simultaneously retains two bits, one nonvolatile bit using the MTJ device and one dynamic bit using the charge storage node Cₛ, thereby significantly decreasing the silicon foot print per bit. The charge storage node Cₛ can have a capacitance equal to the sum of the gate capacitance of N₂ and drain/source capacitance of N₁. The two bits can be independently and nondestructively readout from or written into the MDRAM cell, thereby providing new opportunities for joint enhancement of both performance and energy dissipation. For instance, in a write intensive storage scenario, where a bit requires to be retained for a short period of time, the bit can be stored in a dynamic manner using the charge storage node Cₛ. Alternatively, for a read intensive storage scenario, where a bit of information requires to be retained for a long period of time, the bit may be stored in a nonvolatile manner using the MTJ device. Hence, the MDRAM cell achieves a high speed and energy efficient operation while significantly increases the memory density. Furthermore, the MDRAM can provide functionalities such as, for example, in-situ computing and robustness against side channel cyber attacks. Those skilled in the art will recognize that the new MDRAM cell (e.g. FIG. 1A) can alternatively be implemented using any other resistive memory element other than MTJ, for example, using a memristive device or a phase change memory (PCM) device. Furthermore, each of the three NMOS transistors may be replaced by a p-channel MOS (PMOS) transistor.

FIG. 1A shows a schematic diagram of a new hybrid DRAM cell circuit topology. In this new approach to a hybrid DRAM cell, both of a volatile bit (a dynamic bit) and a nonvolatile bit (e.g. using a MTJ in the exemplary embodiment of FIG. 1A) can be independently and nondestructively accessed for read or write. Access to either of the dynamic bit or the nonvolatile bit does not destroy the other. For example, when the nonvolatile bit is accessed for read or write, write access to the dynamic bit (e.g. Cₛ in the exemplary embodiment of FIG. 1A) is simultaneously available without contention.

Legend:

word-line (WLc), dynamic bit (“c” related to the charge storage node)

bit-line (BLc), dynamic bit

word-line (WLr), nonvolatile bit (“r” related to the resistive element)

bit-line (BLr), nonvolatile bit

lines are referred to as “write lines” for a write operation, and as “read lines” for a read operation.

Write operations: Now in more detail, in the exemplary embodiment of FIG. 1A, N₁ is configured as a write device which provides access to the MDRAM cell for the dynamic write operation (writing a bit into the charge storage node Cₛ). Write device N₁ is coupled to a write word-line (WLc) and a write bit-line (BLc).

Write to dynamic bit: A write operation into the storage node Cₛ can be performed when WLc is transitioned to a logic high state turning on the write device N₁. In order for a “1” to be written into the Cₛ (FIG. 1B), BLc may be set to a logic high state causing Cₛ to maintain a high voltage (V₁-Vₜₕ), where V₁ is the voltage of BLc and Vₜₕ is the threshold voltage of the write device N₁. In order for a “0” to be written into the Cₛ (FIG. 1C), BLc can be set to a logic low state causing the cell storage node Cₛ to maintain a voltage V₀, where the V₀ is the voltage of BLc. Voltage V₀ is effectively larger than the threshold voltage of transistor N₂. Hence, independent of the bit stored within the Cₛ, N₂ is turned on. A proper value for V₀ can be the average value between V₁-Vₜₕ and Vₜₕ which is ½V₁, thereby Vₜₕ<<V₀<<V₁. On completion of the write operation, WLc can be transitioned to the ground causing write device N₁ to be effectively turned off. During the dynamic write operation, both WLr and BLr may be grounded causing N₃ to be turned off.

In FIG. 1A, N₃ is configured as a write/read device and coupled to a word-line (WLr) and a bit-line (BLr). The N₃ provides access to the MDRAM cell for the nonvolatile write operation (writing a bit into the MTJ), and also for the readout of the bits stored within the cell. Device N₂ is ON independent of the bit stored in Cₛ.

Write to the nonvolatile bit: A write operation into the MTJ can be performed when WLr is transitioned to a logic high state turning N₃ on. In order for a “0” to be written into the MTJ (FIG. 1D), BLr may be set to a high voltage and select line (SL) may be set to the ground (or slightly below the ground to boost the current drive capability of N₂). Hence, a current flows through the MTJ from node P to node Q, switching the MTJ to the high resistance state. In order for a “1” to be written into the MTJ (FIG. 1E), BLr may be set to the ground and SL may be set to a high voltage. Hence, a current flows through the MTJ from node Q to node P, switching the MTJ to the low resistance state. On completion of the nonvolatile write operation, WLr can be transitioned to the ground causing device N₃ to be effectively turned off. During the nonvolatile write operation, both WLc and BLc may be grounded causing N₁ to be turned off.

Read operations: In an MDRAM cell, a read operation can begin by setting (WLr) to a high voltage causing device N₃ to be turned on. The read current is related to: (i) the gate-to-source voltage of the N₂, and (ii) the resistance of the MTJ.

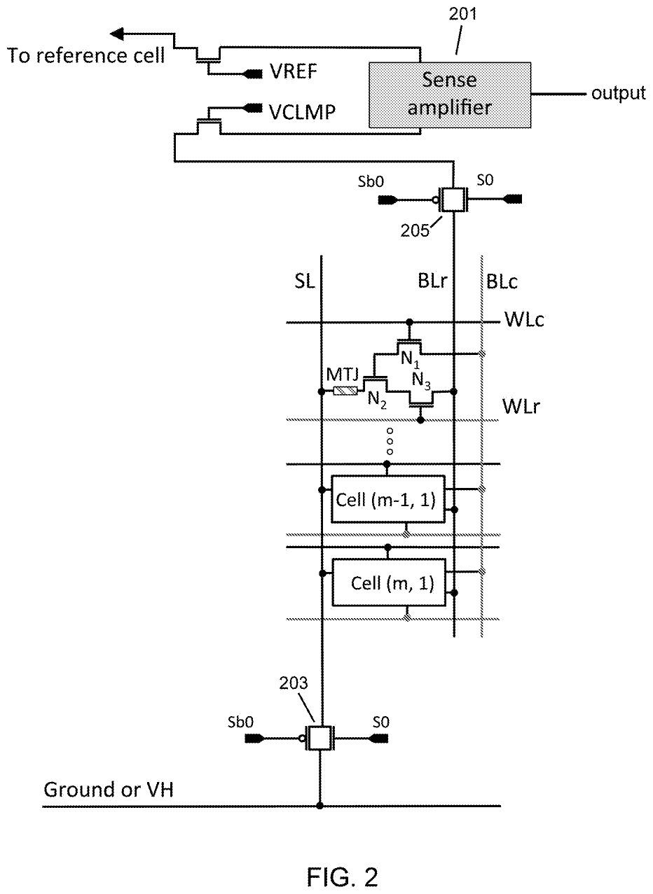

FIG. 2 is a schematic diagram of an exemplary arrangement of a sense amplifier to read the dynamic bit or the nonvolatile bit of a MDRAM cell. There can be one sense amplifier 201 per each column of a memory array. Transmission gates 203 and 205 couple or decouple the column, where (S0,Sb0)=(1,0) couples, and (S0,Sb0)=(0,1) decouples the column. Cells 201a, 201b, 201c, etc. are MDRAM cells as shown, for example, in FIG. 1. Those skilled in the art will understand that a conventional reference generator may be used to provide the reference signal for performing the sensing operation using a sense amplifier, as illustrated in FIG. 2. Once a column, MDRAM cell, bit-line (dynamic or nonvolatile) has been selected, the current from the bit to be read is coupled into the sense amplifier 201 as is the current from the reference cell (not shown in FIG. 2). The bit read as a “0” or a “1” appears at the output of the sense amplifier 201.

Dynamic bit Read: To read the dynamic bit stored within the cell, as illustrated in FIG. 2, SL is charged to a voltage close to the V₀ (as illustrated by VH in FIG. 2), thereby causing the gate-to-source voltage of N₂ to be near zero volt if the stored bit within the Cₛ is “0”. Hence, a significantly larger current may be drawn from BLr if a dynamic “1” is stored in the cell than if a “0” is stored.

Nonvolatile bit Read: To read the nonvolatile bit stored in the cell, as illustrated in FIG. 2, SL is set to the ground, thereby causing the gate-to-source voltage (V_{C}_{ₛ}-V_{SL}) of N₂ to be sufficiently higher than Vₜₕ keeping N₂ turned on independent of the dynamic bit stored in the Cₛ. In this case, therefore, the read current strongly depends on the resistance of the MTJ device. Hence, a larger current may be drawn from BLr if a “1” is stored within the MTJ than if a “0” is stored. Accordingly, the voltage at BLr can fall faster when a dynamic or nonvolatile “1” is stored in the cell than when a dynamic or nonvolatile “0” is stored. A sense amplifier coupled to BLr, as illustrated in FIG. 2, detects the dynamic or nonvolatile bit stored in the memory cell using sensing methods well-known in the art, such as, for example, a comparison of BLr to a reference bit-line.

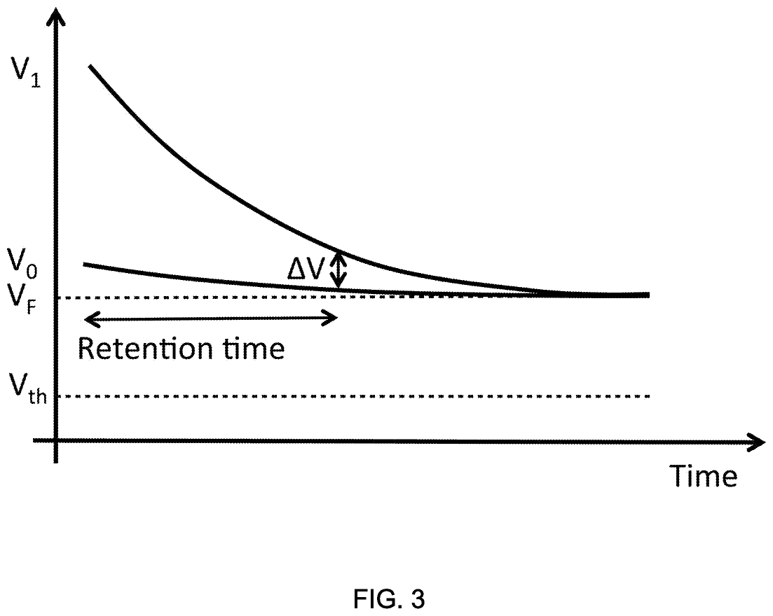

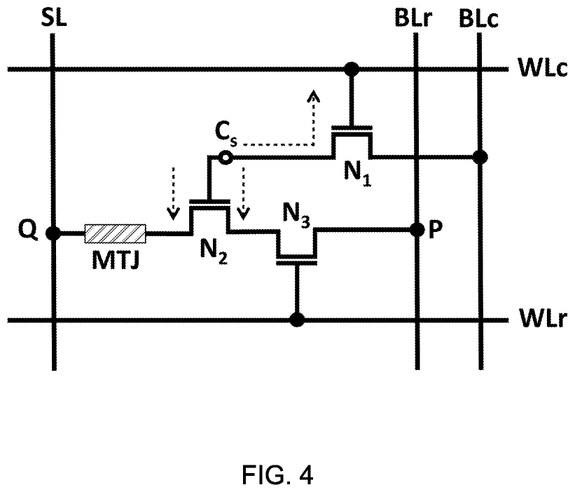

Dynamic bit refresh: In an MDRAM cell, WLc, WLr, BLr, and SL can be pulled to ground and BL_{c} can be held at V_{H} in order for a datum to be retained within the charge storage node Cₛ, where V_{H} can be equal to or slightly higher than V₀. FIG. 3 illustrates an exemplary graph of the voltage level as a function of time at the storage node Cₛ. After a dynamic “0” or “1” is written into the memory cell, voltage level at the Cₛ degrades due to the leakage currents, as illustrated in FIG. 4, and eventually stops at V_{F} near V₀, where the leakage components reach a balance. By setting BL_{c} to V_{H}, the rate of the voltage drop at Cₛ reduces, thereby enhancing the retention time and decreasing the number of time the memory cell needs to be refreshed. The retention time is the time when the voltage difference between the dynamic “1” and “0” reduces to certain ‘ΔV’ that still can be sensed correctly. Similar to other dynamic memory cells, the dynamic bit stored within the MDRAM cell is refreshed by cycles of retention time to prevent bit collapsing.

Those skilled in the art will understand that the exemplary cells described hereinabove are typically part of a memory array of a plurality of cells. The described signaling conditions for read, write, and hold cause the electrical operation of each cell. In some embodiments, the sense amplifier of FIG. 3 can have a direct connection to a power rail and ground rail of a memory or system IC.

In summary, the hybrid memory cell described hereinabove allows for the two bits to be retained simultaneously and accessed independently and nondestructively. The write operation of the dynamic bit is fast, and the dynamic bit is refreshed. The dynamic bit (written into a charge storage node Cₛ) is typically retained for a relatively short period of time, minimizing the refresh operations, i.e. the dynamic bit is written frequently and is write intensive. Bits to be stored for a relatively long period of time and read relatively frequently, are written to the nonvolatile bit (written into a MTJ) which does not need a refresh operation. Frequent reads of the nonvolatile bit and frequent writes of the dynamic bit can happen simultaneously without contention. Thus, a joint enhancement of low energy dissipation with enhanced performance can be achieved.

Part 3 Applications

The MDRAM cell is typically an element in a memory structure of rows and columns of MDRAM cells. There can be a memory integrated circuit (IC) of an array of MDRAM cells, or an array of MDRAM cells as described hereinabove, combined with one or more other types of memory cell. Or, a plurality of MDRAM cells can be incorporated into a system IC as integrated memory for the system. Those skilled in the art will appreciate that the hybrid cell described hereinabove (e.g. FIG. 1A) can be implemented in any suitable integrated technology.

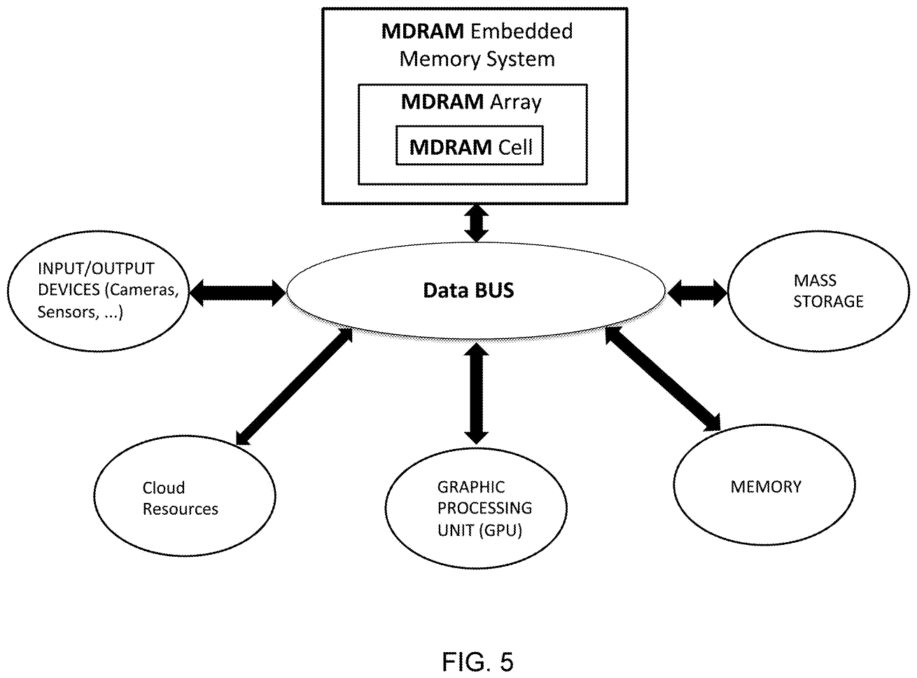

The MDRAM cell may be used in many possible systems with the application in mobile communication, data processing, cloud computing, in-situ computing, and bioelectronics. Furthermore, the MDRAM may inherently enable robustness against side channel cyberattacks. FIG. 5 illustrates an example system where an MDRAM cell may be used to form a cache memory within an integrated circuit (IC). The illustrated system may be a wireless mobile phone, a wearable bioelectronic system, a personal digital assistant, a tablet PC, a notebook PC, a desktop computer, a game station unit, a music player, a server, and a battery driven robot such as a drone or a damage detector robot running into the industrial pipelines.

The phrase “coupled to” includes direct electrical connections as well as communicatively coupled connections. A first transistor second source/drain electrode coupled to a write bit-line is an example of a direct electrical connection. A charge storage node dynamic bit coupled to and written to and read by a corresponding dynamic bit-line and dynamic bit word-line is an example of a communicative or indirect connection, here understood to include one or more intervening switching or control elements, such as for example one or more transistors per control line.

Those skilled in the art will recognize that the present invention is not limited to what described in detail. The present invention may be modified within the spirit and scope of the work. Thus, the description is to be regarded as illustrative instead of restrictive to the exemplary embodiments of the present invention.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

What is claimed is:

1. A hybrid memory cell comprising:
a first transistor comprising a first source/drain electrode coupled to a charge storage node and a gate of a second transistor, a first transistor second source/drain electrode coupled to a dynamic bit-line, and a gate of said first transistor coupled to a dynamic bit word-line;
a resistive memory element coupled between a select line and said second transistor first source/drain electrode; and
a third transistor comprising a third transistor first source/drain electrode coupled to a second source/drain electrode of said second transistor, a third transistor second source/drain electrode coupled to a nonvolatile bit-line, and a gate of said third transistor coupled to a nonvolatile bit word-line.

2. The hybrid memory cell of claim 1, wherein a nonvolatile bit of a hybrid memory cell resides in said resistive memory element, and a dynamic bit of said hybrid memory cell simultaneously resides as a charge state at said charge storage node, such that said hybrid memory cell has an independent and a non-destructive access to both of said nonvolatile bit and said dynamic bit.

3. The hybrid memory cell of claim 2, wherein a read of said nonvolatile bit and a write of said dynamic bit happens simultaneously and without contention.

4. The hybrid memory cell of claim 1, wherein said charge storage node comprises a gate capacitance of said second transistor.

5. The hybrid memory cell of claim 4, wherein said charge storage node further comprises a drain/source capacitance of said first transistor.

6. The hybrid memory cell of claim 1, wherein said second transistor is ON, independent of said dynamic bit stored in said charge storage node.

7. The hybrid memory cell of claim 1, wherein a “1” written into said charge storage node corresponds to a charge storage node voltage of (V₁-Vₜₕ), where V₁ is a voltage of a write bit-line and Vₜₕ is a threshold voltage of said first transistor.

8. The hybrid memory cell of claim 1, wherein said resistive memory element comprises a magnetic tunnel junction (MTJ).

9. The hybrid memory cell of claim 1, wherein said resistive memory element comprises a memristive device.

10. The hybrid memory cell of claim 1, wherein said resistive memory element comprises a phase change memory (PCM) device.

11. The hybrid memory cell of claim 1, further comprising a plurality of additional hybrid memory cells in a column of memory cells of a memory array.

12. A memory array comprising a plurality of columns of hybrid memory cells, each hybrid memory cell of each column comprising a dynamic bit charge storage node coupled to and accessed via a dynamic bit word-line, a dynamic bit-line, and a select line, a nonvolatile bit resistive memory element coupled to and accessed via a nonvolatile bit-line, a nonvolatile bit word-line, and said select line, such that there is a simultaneous and independent and non-destructive access to both of said dynamic bit and said nonvolatile bit.

13. A hybrid memory cell method comprising:
providing a hybrid memory cell comprising a dynamic bit having a charge storage node and a nonvolatile bit comprising a resistive memory element;
writing to a dynamic bit charge node at a gate of second transistor of a hybrid memory cell via dynamic bit-line coupled to a first transistor; or
writing to a nonvolatile bit resistive memory element of said hybrid memory cell via a nonvolatile bit-line coupled to a third transistor; and
wherein said nonvolatile bit and said dynamic bit of said hybrid memory cell simultaneously reside in said hybrid memory cell such that said hybrid memory cell has an independent and a non-destructive access to both of said nonvolatile bit and said dynamic bit.

14. The hybrid memory cell method of claim 13, wherein said step of independent and a non-destructive access comprises a read or a write of either of said dynamic bit or said nonvolatile bit by a sense amplifier.
